(19) United States
(12) Patent Application Publication
(10) Pub. No.: US 2026/0059738 A1
(43) Pub. Date: Feb. 26, 2026

(54) SEMICONDUCTOR MEMORY DEVICE

(71) Applicant: Samsung Electronics Co., Ltd., Suwon-si (KR)

(72) Inventors: Hoseok Lee, Suwon-si (KR); Chulkwon Park, Suwon-si (KR); Sunggyeong Lee, Suwon-si (KR); Young Seok Park, Suwon-si (KR); Hyun-Chul Yoon, Suwon-si (KR)

(21) Appl. No.: 19/261,908

(22) Filed: Jul. 7, 2025

(30) Foreign Application Priority Data
Aug. 22, 2024 (KR) 10-2024-0113122

(51) Int. Cl. H10B 12/00; G11C 11/408; H01L 23/00; H01L 25/065; H01L 25/18; H10B 80/00

(52) U.S. Cl. CPC H10B 12/30; G11C 11/4085; H01L 24/08; H01L 25/0657; H01L 25/18; H10B 12/50; H10B 80/00; H01L 2224/08145; H01L 2924/1431; H01L 2924/1436

(57) ABSTRACT

An example semiconductor memory device may include a first conductive line extending in a first direction perpendicular to a substrate, a first gate electrode extending in a second direction, crossing the first direction, on the substrate, a first semiconductor pattern extending from the first conductive line to the first gate electrode, a second gate electrode spaced apart from the first gate electrode on the substrate and extending in the second direction, and a contact extending in the first direction and electrically connected with the first gate electrode and the second gate electrode.

### CROSS-REFERENCE TO RELATED APPLICATION

This application claims priority to and the benefit of Korean Patent Application No. 10-2024-0113122 filed in the Korean Intellectual Property Office on Aug. 22, 2024, the entire contents of which is incorporated herein by reference.

### BACKGROUND

In order to increase the integration of DRAM, a structure has been proposed in which unit elements consisting of transistors and capacitors are horizontally formed and vertically stacked. As the demand for high-integration and high-capacity memory increases, research is being conducted to increase the number of layers in the multilayer structure.

To control the multilayer structure, a stepped wiring structure is utilized. As the number of layers of the multilayer structure increases, the wiring length becomes longer, which may deteriorate the electrical performance.

### SUMMARY

The present disclosure relates to a semiconductor memory device having improved performance of sensing and amplifying operations.

The present disclosure relates to a semiconductor memory device having improved RC delay due to the wiring.

In some implementations, a semiconductor memory device may include a first conductive line extending in a first direction perpendicular to a substrate, a first gate electrode extending in a second direction crossing the first direction, on the substrate, a first semiconductor pattern extending from the first conductive line to the first gate electrode, a second gate electrode spaced apart from the first gate electrode on the substrate, and extending in the second direction, and a contact extending in the first direction, and electrically connected to the first and second gate electrodes.

In some implementations, a semiconductor memory device may include a first conductive line extending in a first direction perpendicular to a substrate, a first gate electrode extending in a second direction crossing the first direction, on the substrate, a first semiconductor pattern extending from the first conductive line to the first gate electrode, a second gate electrode spaced apart from the first gate electrode in a third direction crossing the first and second directions, and extending in the second direction on the substrate, and a contact extending in the first direction, and electrically connected to the first and second gate electrodes.

In some implementations, a semiconductor memory device may include a first conductive line extending in a first direction perpendicular to a substrate, a first gate electrode extending in a second direction crossing the first direction, on the substrate, a second gate electrode extending in the second direction, on the first gate electrode, a first semiconductor pattern extending from the first conductive line to the first gate electrode, and a contact extending in the first direction, and electrically connected to the first and second gate electrodes.

In some implementations, a semiconductor memory device may include a cell array structure comprising a cell array region comprising a plurality of wordlines comprising first and second wordlines extending in a first direction on a first substrate, and stacked in a second direction perpendicular to the first substrate and a plurality of memory cells connected to the plurality of wordlines, and a contact region comprising a contact electrically connected to the first and second wordlines and extending in the second direction, wherein, in the contact region, the plurality of wordlines protrude in the first direction as it is closer to the first substrate, a peripheral circuit structure having at least a portion planarly overlapping with the contact region, and comprising a wordline driver electrically connected to the plurality of wordlines through the contact, and a contact plug extending in the second direction from an input/output pad disposed on an upper surface of the cell region to penetrate at least a portion of the cell region, and electrically connected to a circuit element of the peripheral circuit structure.

### BRIEF DESCRIPTION OF THE DRAWINGS

FIG. 1 is a perspective view showing a portion of an example of a semiconductor memory device.

FIG. 2 is an example top plan view showing a portion of the stacking structures of FIG. 1.

FIG. 3 is an example cross-sectional view taken along line A-A′ of FIG. 2.

FIG. 4 is an example cross-sectional view taken along line B-B′ of FIG. 2.

FIG. 5 is an example cross-sectional view taken along line C-C′ of FIG. 2.

FIG. 6 is a circuit diagram showing an example of a memory cell array included in a semiconductor memory device.

FIG. 7 is a perspective view showing a portion of an example of a semiconductor memory device.

FIG. 8 is an example top plan view showing a portion of the stacking structures of FIG. 7.

FIG. 9 is an example cross-sectional view taken along line D-D′ of FIG. 8.

FIG. 10 is an example cross-sectional view taken along line E-E′ of FIG. 8.

FIG. 11 is a circuit diagram showing an example of a memory cell array included in a semiconductor memory device.

FIG. 12 is a perspective view showing an example of a semiconductor memory device.

FIG. 13 is an example cross-sectional view taken along line X-X′ of FIG. 12.

FIG. 14 is a perspective view showing an example of a semiconductor memory device.

FIG. 15 is an example cross-sectional view taken along line Y-Y′ of FIG. 14.

FIG. 16 is a block diagram showing an example of an electronic device.

### DETAILED DESCRIPTION

Hereinafter, the present disclosure will be described in detail hereinafter with reference to the accompanying drawings, in which implementations of the present disclosure are shown. As those skilled in the art would realize, the described implementations may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

In addition, unless explicitly described to the contrary, the word “comprise”, and variations such as “comprises” or “comprising”, will be understood to imply the inclusion of stated elements but not the exclusion of any other elements.

Also, throughout the specification, when it is said that ‘one component is placed adjacent to another component’, it means that one component and another component are placed next to each other so that no component that is identical or similar to one component between the one component and another component, or one component and another component are in contact with each other. For example, ‘X’ being placed adjacent to ‘Y’ includes ‘X’ and ‘Y’ being adjacent so that no component identical or similar to ‘X’ is placed between ‘X’ and ‘Y’, or ‘X’ and ‘Y’ are in contact with each other

Additionally, specific numbers described in a claim, even if explicitly recited within the claim, should not be construed as limiting the specific number in claims where such citation does not exist. For example, as an aid to understanding, the following appended claims may contain usage of the introductory phrases “at least one” and “one or more” to introduce claim recitations. However, the use of such a phrase should not be understood as a limitation described by the unclear article “one” for the sake of one example.

Furthermore, in those instances where a convention analogous to “at least one of A. B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In some implementations, ‘a module’, ‘a unit’, or ‘a part’ perform at least one function or operation, and may be realized as hardware, such as a processor or integrated circuit, software that is executed by a processor, or a combination thereof.

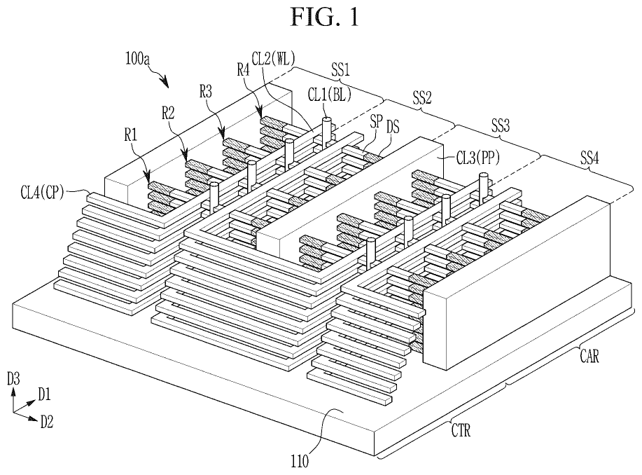

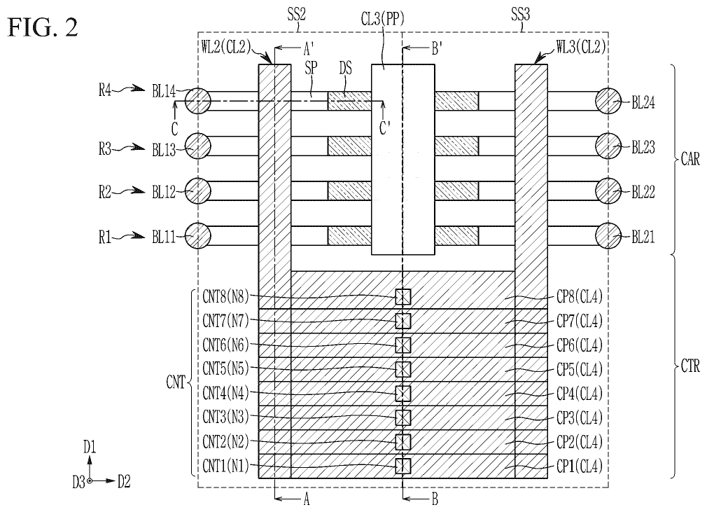

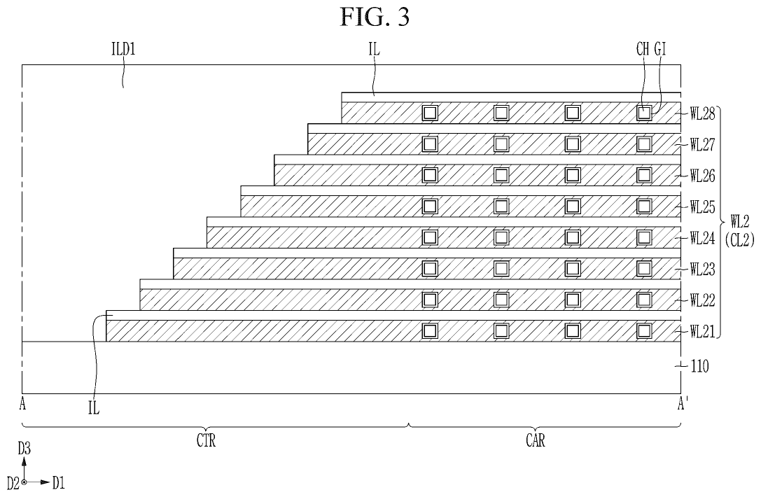

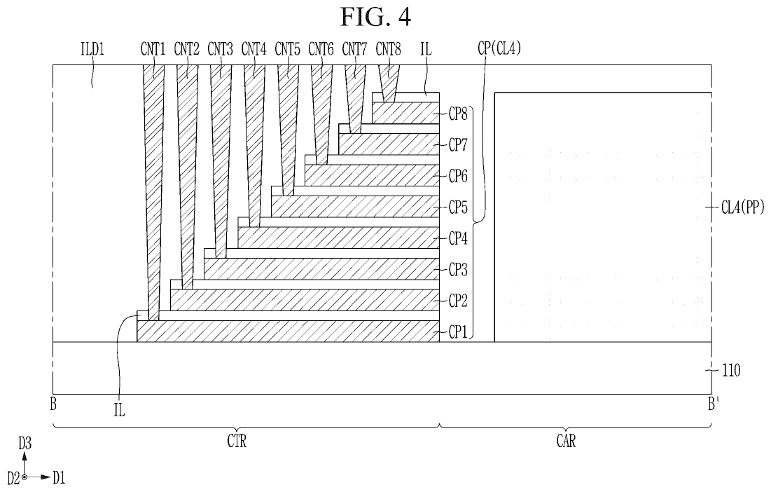

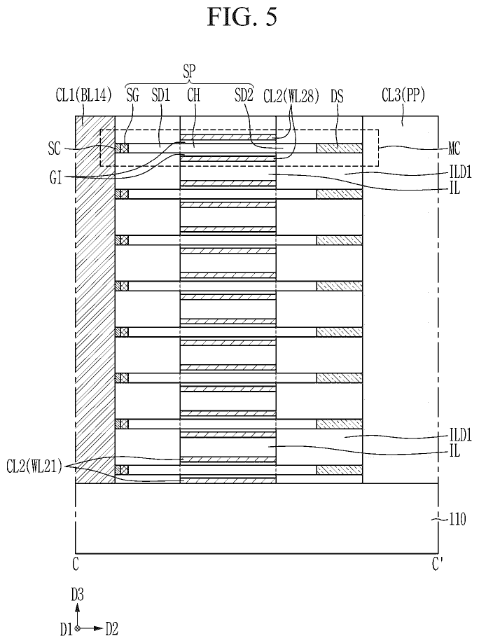

FIG. 1 is a perspective view showing a portion of an example of a semiconductor memory device. FIG. 2 is an example top plan view showing a portion of the stacking structures of FIG. 1. FIG. 3 is an example cross-sectional view taken along line A-A′ of FIG. 2. FIG. 4 is an example cross-sectional view taken along line B-B′ of FIG. 2. FIG. 5 is an example cross-sectional view taken along line C-C′ of FIG. 2. Specifically, FIG. 2 is a top plan view showing second and third stacking structures SS2 and SS3 of a memory cell array 100a.

Referring to FIG. 1 to FIG. 5, the semiconductor memory device may include the memory cell array 100a. The memory cell array 100a may include a plurality of bitlines BL extending along a third direction D3, a plurality of wordlines WL stacked along the third direction D3 and extending along a first direction D1, and a plurality of memory cells MC connected to the plurality of bitlines BL and the plurality of wordlines WL and disposed at a location where the plurality of bitlines BL and the plurality of wordlines WL cross each other.

In some implementations, the memory cell MC of the memory cell array 100a may include a volatile dynamic random-access memory (DRAM) element. A unit element of the DRAM element may include one cell transistor and one capacitor, and may have a 1T1C structure.

The memory cell array 100a may include a substrate 110, first to fourth stacking structures SS1 to SS4, a plurality of first conductive lines CL1, a first interlayer insulating layer ILD1, and a plurality of third conductive lines CL3.

The substrate 110 may include a cell array region CAR and a contact region CTR. The substrate 110 may be a silicon substrate, a germanium substrate, or a silicon-germanium substrate. In some implementations, a separate insulation layer may be disposed on an upper surface of the substrate 110.

The first to fourth stacking structures SS1 to SS4 may be disposed on the substrate 110. Each of the first to fourth stacking structures SS1 to SS4 may extend in the first direction D1 to be parallel to each other. The first to fourth stacking structures SS1 to SS4 may be arranged along a second direction D2. In some implementations, the substrate 110 and the first to fourth stacking structures SS1 to SS4 may be vertically spaced apart in the third direction D3, interposing an insulation layer.

The plurality of first conductive lines CL1 penetrating the first to fourth stacking structures SS1 to SS4 may be disposed on the cell array region CAR of the substrate 110. The plurality of first conductive lines CL1 may have a column shape or a bar shape extending in a direction (i.e., the third direction D3) perpendicular to the upper surface of the substrate 110. The plurality of first conductive lines CL1 may be arranged the first direction D1, between the first and second stacking structures SS1 and SS2 or between the third and fourth stacking structures SS3 and SS4. In some implementations, the plurality of first conductive lines CL1 may be the bitline BL connected to the memory cell MC.

The plurality of first conductive lines CL1 may include 1_1-th to 1_4-th bitlines BL11 to BL14 corresponding to first to fourth columns R1 to R4 and arranged in the first direction D1 and 2_1-th to 2_4-th bitlines BL21 to BL24 corresponding to the first to fourth columns R1 to R4 and arranged in the first direction D1. The 1_1-th to 1_4-th bitlines BL11 to BL14 and the 2_1-th to 2_4-th bitlines BL21 to BL24 may be spaced apart from each other in the second direction D2.

In some implementations, the 1_1-th to 1_4-th bitlines BL11 to BL14 and the 2_1-th to 2_4-th bitlines BL21 to BL24 may be local bitlines directly connected to the memory cell MC. The 1_1-th to 1_4-th bitlines BL11 to BL14 and the 2_1-th to 2_4-th bitlines BL21 to BL24 may extend in the third direction D3 by a predetermined length, making it easy to maintain the characteristics of the signal transferred to a sense amplifier circuit. Through the above-described structure of the 1_1-th to 1_4-th bitlines BL11 to BL14 and the 2_1-th to 2_4-th bitlines BL21 to BL24, RC delay characteristics of signals transferred to the sense amplifier circuit may be easily adjusted to be uniform, thereby improving the performance of the sensing and amplifying operation of the semiconductor memory device.

Each of the plurality of first conductive lines CL1 may be disposed adjacent to a semiconductor pattern SP of the first to fourth columns R1 to R4 corresponding thereto, respectively, and electrically connected to the first to fourth stacking structures SS1 to SS4, and without being limited thereto, each of the first conductive lines CL1 may directly contact the semiconductor pattern SP of the first to fourth columns R1 to R4 corresponding thereto.

The plurality of first conductive lines CL1 may include a conducting material. As an example, the conducting material may be one among a doped semiconductor material (doped silicon, doped germanium, or the like), a conductive metal nitride (titanium nitride, tantalum nitride, or the like), a metal (tungsten, titanium, tantalum, or the like), and a metal-semiconductor compound (tungsten silicide, cobalt silicide, titanium silicide, or the like).

Taking FIG. 5 as an example, the first conductive line CL1 penetrating the second stacking structure SS2 and corresponding to a 1_4-th bitline BL14 may be adjacent to sidewalls of the semiconductor pattern SP of a fourth column R4, and a silicide layer SC may be interposed between the first conductive line CL1 and the semiconductor pattern SP. The silicide layer SC may include a metal-semiconductor compound (tungsten silicide, cobalt silicide, titanium silicide, or the like).

Each of the first to fourth stacking structures SS1 to SS4 may include a plurality of semiconductor patterns SP, a plurality of second conductive lines CL2, a plurality of information storage elements DS, and a plurality of fourth conductive lines CL4.

Each of the first to fourth stacking structures SS1 to SS4 may include the semiconductor pattern SP of the first to fourth columns R1 to R4 on the cell array region CAR of the substrate 110. Each of the first to fourth columns R1 to R4 may include the plurality of semiconductor patterns SP that are vertically stacked and planarly overlapping with each other. The plurality of semiconductor patterns SP may be disposed at a location where the first conductive line CL1 and the plurality of second conductive lines CL2 cross each other. For example, although the number of the semiconductor patterns SP of each of the first to fourth columns R1 to R4 is shown as 8 as an example, it is not particularly limited thereto. The first to fourth columns R1 to R4 may be arranged along the first direction D1 to be spaced apart from each other.

Each of the first to fourth stacking structures SS1 to SS4 may include the plurality of semiconductor patterns SP and the first interlayer insulating layer ILD1 that are alternately stacked. The plurality of semiconductor patterns SP vertically stacked along the third direction D3 may be vertically spaced apart from each other by the first interlayer insulating layer ILD1.

The first interlayer insulating layer ILD1 may be interposed between a pair of semiconductor patterns SP perpendicularly adjacent to each other. The first interlayer insulating layer ILD1 may be selected from the group consisting of a silicon oxide layer, a silicon nitride layer, a silicon oxide nitride layer, a carbon-containing silicon oxide layer, a carbon-containing silicon nitride layer, and a carbon-containing silicon oxide nitride layer.

Each of the semiconductor patterns SP may have a line shape, a bar shape, or a column shape extending in the second direction D2. For example, the semiconductor pattern SP may include silicon, germanium, silicon-germanium or indium gallium zinc oxide (IGZO). Each of the semiconductor patterns SP may include a first extrinsic region SD1, a second extrinsic region SD2, an end point layer SG, and a channel region CH.

Each of the first and second extrinsic regions SD1 and SD2 may be disposed on both sidewalls of the channel region CH based on the second direction D2. That is, the channel region CH may be disposed between the first and second extrinsic regions SD1 and SD2. The first and second extrinsic regions SD1 and SD2 may have a first conductivity type (e.g., N-type). The first extrinsic region SD1 may be alternately stacked with the first interlayer insulating layer ILD1 in the third direction D3. In the same way, the second extrinsic region SD2 may be alternately stacked with the first interlayer insulating layer ILD1 in the third direction D3. The first and second extrinsic regions SD1 and SD2 vertically adjacent to each other may be vertically spaced apart from each other by the first interlayer insulating layer ILD1.

The end point layer SG may be a layer additionally formed between the semiconductor pattern SP and the first conductive line CL1. The end point layer SG may include a semiconductor element having a relatively narrow band gap, and the end point layer SG may include silicon-germanium.

The channel region CH may not be doped, or may have a second conductivity type (e.g., P-type) that is different from the first conductivity type. The channel region CH may correspond to a channel of the cell transistor. The first and second extrinsic regions SD1 and SD2 may correspond to source and drain of the cell transistor, respectively.

The plurality of second conductive lines CL2 may be vertically stacked, and may be vertically spaced apart from each other by a plurality of insulation layers IL. The insulation layer IL may be interposed between a pair of second conductive line CL2 perpendicularly adjacent to each other. The insulation layer IL may be selected from the group consisting of a silicon oxide layer, a silicon nitride layer, a silicon oxide nitride layer, a carbon-containing silicon oxide layer, a carbon-containing silicon nitride layer, and a carbon-containing silicon oxide nitride layer.

Although drawings illustrate that the insulation layer IL and the first interlayer insulating layer ILD1 are distinguished, the insulation layer IL and the first interlayer insulating layer ILD1 may be disposed as one material layer.

The plurality of second conductive lines CL2 may have a line shape or a bar shape extending in the first direction D1. The second conductive line CL2 may extend from the cell array region CAR of the substrate 110 to the contact region CTR.

Each of the plurality of second conductive lines CL2 may have a stepped structure on the contact region CTR of the substrate 110. Lengths of the plurality of second conductive lines CL2 in the first direction D1 stacked on the contact region CTR may be longer as it is closer to the upper surface of the substrate 110. Referring to FIG. 2 and FIG. 3, the plurality of second conductive lines CL2 may further extend in an opposite direction of the first direction D1 as it is closer to the substrate 110. The second conductive line CL2 disposed in a lower portion may further protrude than a sidewall of the second conductive line CL2 disposed in an upper portion.

The plurality of second conductive lines CL2 may be penetrated in the second direction D2 by each of the plurality of semiconductor patterns SP corresponding thereto. That is, each of the second conductive lines CL2 may surround the channel region CH of the plurality of semiconductor patterns SP corresponding thereto. A gate insulating layer GI may be disposed between the second conductive line CL2 and the channel region CH of the semiconductor pattern SP. However, the spirit and scope of the present disclosure is not limited to the above-described penetration structure, and the plurality of second conductive lines CL2 may be disposed on a sidewall of the channel region CH.

Each of the plurality of second conductive lines CL2 may operate as a gate electrode, and the plurality of second conductive lines CL2 may be the wordline WL connected to gate of the cell transistor.

With an example of FIG. 2, the plurality of second conductive lines CL2 may include a second wordline WL2 included in the second stacking structure SS2 and extending in the first direction and a third wordline WL3 included in the third stacking structure SS3 and extending in the first direction.

The second wordline WL2 may be vertically stacked in the third direction D3, and vertically spaced apart from each other by the plurality of insulation layers IL. In the same way, the third wordline WL3 may be vertically stacked in the third direction D3, and vertically spaced apart from each other by the plurality of insulation layers IL. The insulation layer IL may be interposed between a pair of second wordlines WL2 perpendicularly adjacent to each other and between a pair of third wordlines WL3 perpendicularly adjacent to each other. Since it is obvious that the description on the second wordline WL2 may be applied to the third wordline WL3, the description below will be made based on the second wordline WL2.

As an example, the second wordline WL2 may include 2_1-th to 2_8-th wordlines WL21 to WL28 stacked in the third direction D3 from the substrate 110. The 2_1-th to 2_8-th wordlines WL21 to WL28 may be vertically spaced apart from each other by the plurality of insulation layers IL.

The 2_1-th to 2_8-th wordlines WL21 to WL28 may extend from the cell array region CAR of the substrate 110 to the contact region CTR. The second wordline WL2 may have a stepped structure on the contact region CTR of the substrate 110. The length in the first direction D1 of the second wordline WL2 stacked on the contact region CTR may be longer as it is closer to the upper surface of the substrate 110. Referring to FIG. 2 and FIG. 3, the second wordline WL2 may further extend in the opposite direction of the first direction D1 as it is closer to the substrate 110. The second wordline WL2 disposed in a lower portion may further protrude than a sidewall of the second wordline WL2 disposed in an upper portion.

For example, the length of the 2_1-th wordline WL21 in a lowermost portion among the stacked second wordlines WL2 may become longer than length of each of the remaining 2_2-th to 2_8-th wordlines WL22 to WL28. The length of the 2_8-th wordline WL28 in an uppermost portion among the stacked second wordlines WL2 may be shorter than length of each of the remaining 2_1-th to 2_7-th wordlines WL21 to WL27.

Although not shown in FIG. 2 to FIG. 5, each of the first and fourth stacking structures SS1 and SS4 may include wordline corresponding to the second and third wordlines WL2 and WL3 of the second and third stacking structures SS2 and SS3.

The second conductive line CL2 may include a conducting material, and the conducting material may be one of a doped semiconductor material, a conductive metal nitride, a metal, and a metal-semiconductor compound.

The gate insulating layer GI may include a single layer selected from among a high-k dielectric layer, a silicon oxide layer, a silicon nitride layer, and a silicon oxide nitride layer, or a combination thereof. For example, the high-k dielectric layer may include at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

Each of the first to fourth stacking structures SS1 to SS4 may further include the plurality of information storage elements DS that are vertically stacked. The plurality of information storage elements DS that are vertically stacked may be vertically spaced apart from each other by the first interlayer insulating layer ILD1. The plurality of information storage elements DS may extend in the second direction D2 from the semiconductor patterns SP, respectively.

The plurality of information storage elements DS may directly contact the plurality of semiconductor patterns SP. For example, the information storage elements DS may be located at substantially the same level as the semiconductor patterns SP, respectively. The information storage elements DS may be connected to the second extrinsic region SD2 of the semiconductor patterns SP, respectively.

Although not shown in the drawings, each of the information storage elements DS may include a first electrode, a second electrode different from the first electrode, and a dielectric layer interposed between the first and second electrode, which are different from each other. The dielectric layer may include at least one of a metal oxide such as hafnium oxide, zirconium oxide, aluminum oxide, lanthanum oxide, tantalum oxide and titanium oxide, and a dielectric material of a perovskite structure such as SrTiO3(STO), (Ba,Sr)TiO3(BST), BaTiO3, PZT, PLZT. The information storage element DS may be a capacitor of the memory cell MC.

On the cell array region CAR of the substrate 110, the third conductive line CL3 extending in the first direction D1 to be parallel to the first to fourth stacking structures SS1 to SS4 may be provided. The third conductive line CL3 may be disposed between the second and third stacking structures SS2 and SS3, on a first side of a first stacking structure SS1, and on a first side of a fourth stacking structure SS4, and the third conductive line CL3 may be disposed to be spaced apart from each other in the second direction D2.

A first-coming third conductive line CL3 may be commonly connected to second electrodes of a capacitor of the first stacking structure SS1, and a second-coming third conductive line CL3 may be commonly connected to second electrodes of a capacitor of the second and third stacking structures SS2 and SS3, and may be commonly connected to second electrodes of a capacitor of the fourth stacking structure SS4.

The third conductive line CL3 may include a conducting material, and the conducting material may be one of a doped semiconductor material, a conductive metal nitride, a metal, and a metal-semiconductor compound. In some implementations, the third conductive line CL3 may be a ground wire PP.

The semiconductor pattern SP and the information storage element DS disposed between the first conductive line CL1 and the third conductive line CL3 and penetrating the second conductive line CL2 may be driven as the memory cell MC.

The plurality of fourth conductive lines CL4 may extend in the second direction D2 from the contact region CTR, and electrically connect the second conductive line CL2 disposed at substantially the same height and spaced apart in the second direction D2. The plurality of fourth conductive lines CL4 may be in contact with the plurality of second conductive lines CL2 disposed at substantially the same height, and the plurality of fourth conductive lines CL4 may have a line shape or a bar shape extending in the second direction D2.

Taking FIG. 2 to FIG. 4 as an example, the plurality of fourth conductive lines CL4 may be a connection pad CP on which a contact CNT lands, and the plurality of fourth conductive lines CL4 may include first to eighth connection pads CP1 to CP8 stacked in the third direction D3 from the substrate 110. The first to eighth connection pads CP1 to CP8 may be vertically spaced apart from each other by the plurality of insulation layers IL.

A first connection pad CP1 may be in contact with a 2_1-th wordline W21, and may extend in the second direction D2 to contact the third wordline WL3 corresponding to the 2_1-th wordline W21. A second connection pad CP2 may be in contact with a 2_2-th wordline W22, and may extend in the second direction D2 to contact the third wordline WL3 corresponding to the 2_2-th wordline W22. A third connection pad CP3 may be in contact with a 2_3-th wordline W23, and may extend in the second direction D2 to contact the third wordline WL3 corresponding to the 2_3-th wordline W23. A fourth connection pad CP4 may be in contact with a 2_4-th wordline W24, and may extend in the second direction D2 to contact the third wordline WL3 corresponding to the 2_4-th wordline W24. A fifth connection pad CP5 may be in contact with a 2_5-th wordline W25, and may extend in the second direction D2 to contact the third wordline WL3 corresponding to the 2_5-th wordline W25. A sixth connection pad CP6 may be in contact with a 2_6-th wordline W26, and may extend in the second direction D2 to contact the third wordline WL3 corresponding to the 2_6-th wordline W26. A seventh connection pad CP7 may be in contact with a 2_7-th wordline W27, and may extend in the second direction D2 to contact the third wordline WL3 corresponding to the 2_7-th wordline W27. An eighth connection pad CP8 may be in contact with a 2_8-th wordline W28, and may extend in the second direction D2 to contact the third wordline WL3 corresponding to the 2_8-th wordline W28.

Although drawings illustrate that the connection pad CP and a second wordline W2 and a third wordline W3 are distinguished, the connection pad CP, the second wordline W2, and the third wordline W3 disposed at substantially the same height may be disposed as one conductive layer.

The connection pad CP may have a stepped structure on the contact region CTR of the substrate 110. A length of the connection pad CP in the first direction D1 stacked on the contact region CTR may be longer as it is closer to the upper surface of the substrate 110. Referring to FIG. 4, the connection pad CP may further extend in the opposite direction of the first direction D1 as it is closer to the substrate 110. The connection pad CP disposed in a lower portion may further protrude than a sidewall of the connection pad CP disposed in an upper portion.

For example, a length of the first connection pad CP1 in the first direction D1 in a lowermost portion among the stacked connection pads CP may become longer than a length of the first direction D1 of each of the remaining second to eighth wordlines CP2 to CP8. A length of the eighth connection pad CP8 in the first direction D1 in an uppermost portion among the stacked connection pads CP may be shorter than the length of the first direction D1 of each of the remaining first to seventh wordlines CP1 to CP7.

In addition, the connection pad CP may be spaced apart from the third conductive line CL3 in the first direction D1. The first interlayer insulating layer ILD1 may be disposed between the connection pad CP and the third conductive line CL3.

The connection pad CP may contact the contact CNT in a region exposed by the first interlayer insulating layer ILD1. The contact CNT may extend in an opposite direction of the third direction D3, and land on a region exposed by the first interlayer insulating layer ILD1 of the connection pad CP corresponding thereto. The contact CNT may include first to eighth contacts CNT1 to CNT8 corresponding to the first to eighth connection pads CP1 to CP8.

As an example, the first contact CNT1 may extend in the opposite direction of the third direction D3, and land on a protruding region of the first connection pad CP1. The first contact CNT1 may contact the first connection pad CP1, and may be electrically connected to the 2_1-th wordline W21 and the third wordline WL3 corresponding to the 2_1-th wordline W21. In the same way, each of the second to seventh contacts CNT2 to CNT7 may extend in the opposite direction of the third direction D3, and land on a protruding region of each of the second to seventh connection pads CP2 to CP7. Each of the second to seventh contacts CNT2 to CNT7 may contact each of the second to seventh connection pads CP2 to CP7, and electrically connected to the second wordline WL2 and the third wordline WL3 corresponding thereto.

The eighth contact CNT8 may extend in the opposite direction of the third direction D3 and land on the exposed region of the eighth connection pad CP8. The eighth contact CNT8 may contact the eighth connection pad CP8, and may be electrically connected to the 2_1-th wordline W21 and the third wordline WL3 corresponding to the 2_8-th wordline W28.

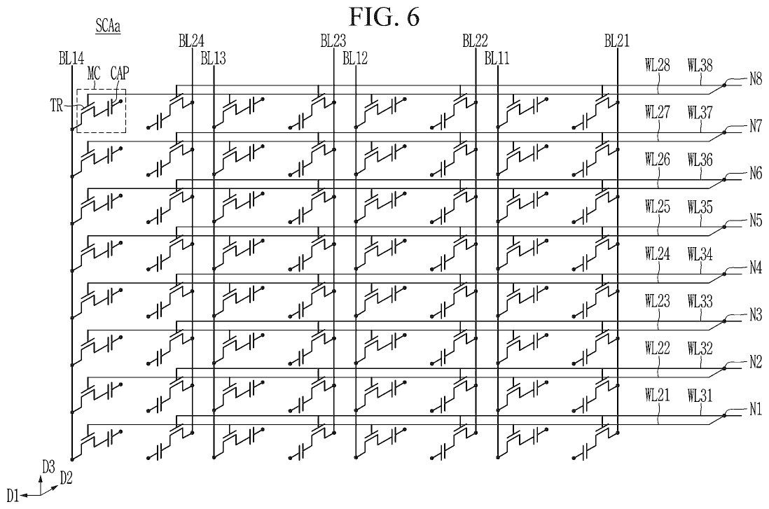

Each of the first to eighth contacts CNT1 to CNT8 may correspond to first to eighth nodes N1 to N8 of FIG. 6 to be described later, and the first to eighth contacts CNT1 to CNT8 may be a common node connected to the second and third wordlines WL2 and WL3 corresponding thereto. Through the above-described structure of the second wordline WL2, the third wordline WL3, and the connection pad CP, the second wordline WL2 and the third wordline WL3 may be activated together.

In some implementations, the first and second stacking structures SS1 and SS2 and the third and fourth stacking structures SS3 and SS4 may have substantially the same structure. The first and second stacking structures SS1 and SS2 and the third and fourth stacking structures SS3 and SS4 may be symmetrical to each other. The first and second stacking structures SS1 and SS2 may be mirror-symmetrical to each other based on the first conductive line CL1. The third and fourth stacking structures SS3 and SS4 may be mirror-symmetrical to each other based on the first conductive line CL1. The second and third stacking structures SS2 and SS3 may be mirror-symmetrical to each other based on the third conductive line CL3 disposed between them. Although not shown, the memory cell array 100a may include a stacking structures having have substantially the same structure as the second and third stacking structures SS2 and SS3, and the stacking structures may be arranged in the second direction D2.

According to the semiconductor memory device, through the above-described structure of the second wordline WL2, the third wordline WL3, and the connection pad CP, the number of the simultaneously driven memory cells may be increased and the wiring length with respect to one wordline may be reduced. According to the reduced wiring length, the wire resistance and the parasitic capacitor between wordlines stacked in the third direction D3 may be reduced. According to the semiconductor memory device, through the improved wire resistance and parasitic capacitor, the RC delay caused by wordlines as the memory cells are densely disposed may be improved.

FIG. 6 is a circuit diagram showing an example of the memory cell array included in the semiconductor memory device. Specifically, the circuit diagram of FIG. 6 is a circuit diagram showing a sub-cell array SCAa that corresponds to the second to third stacking structures SS2 and SS3 of FIG. 1 to FIG. 5 and is a portion of the memory cell array 100a.

Referring to FIG. 1 to FIG. 6, the memory cell array 100a may include the sub-cell array SCAa. The sub-cell array SCAa may be arranged along the second direction D2.

The sub-cell array SCAa may include a plurality of bitlines BL11 to BL14 and BL21 to BL24, a plurality of wordlines WL21 to WL28 and WL31 to WL38, and a plurality of memory cells MC. The memory cell MC may be disposed at a location where the plurality of bitlines BL11 to BL14 and BL21 to BL24 and the plurality of wordlines WL21 to WL28 and WL31 to WL38 cross each other.

Each of the plurality of bitlines BL11 to BL14 and BL21 to BL24 may be conductive patterns (e.g., metal line) perpendicularly extending from the substrate in the third direction D3, and disposed on the substrate. The plurality of bitlines BL11 to BL14 and BL21 to BL24 may include the 1_1-th to 1_4-th bitlines BL11 to BL14 and the plurality of bitlines BL11 to BL14 and BL21 to BL24. The 1_1-th to 1_4-th bitlines BL11 to BL14 may be spaced apart from each other in the first direction D1, and the 2_1-th to 2_4-th bitlines BL21 to BL24 may be spaced apart from each other in the first direction D1. In addition, the 1_1-th to 1_4-th bitlines BL11 to BL14 may be spaced apart from the 2_1-th to 2_4-th bitlines BL21 to BL24 the second direction D2, respectively.

The plurality of wordlines WL21 to WL28 and WL31 to WL38 may be conductive patterns (e.g., metal line) extending in the first direction D1 on the substrate. The plurality of wordlines WL21 to WL28 and WL31 to WL38 may include the 2_1-th to 2_8-th wordlines WL21 to WL28 and 3_1-th to 3_8-th wordlines WL31 to WL38. The 2_1-th to 2_8-th wordlines WL21 to WL28 may be stacked perpendicularly to the substrate, and may be spaced apart from each other in the third direction D3. The 3_1-th to 3_8-th wordlines WL31 to WL38 may be stacked perpendicularly to the substrate, and may be spaced apart from each other in the third direction D3.

In addition, each of the 2_1-th to 2_8-th wordlines WL21 to WL28 may be spaced apart from each of the 3_1-th to 3_8-th wordlines WL31 to WL38 disposed at substantially the same height in the second direction D2. Each of the 2_1-th to 2_8-th wordlines WL21 to WL28 may be electrically connected to each of the 3_1-th to 3_8-th wordlines WL31 to WL38 through the first to eighth nodes N1 to N8. As an example, the 2_1-th wordline WL21 may be electrically connected to the 3_1-th wordline WL31 disposed at substantially the same height through a first node N1, and the 2_1-th wordline WL21 and the 3_1-th wordline WL31 may activated together through the first node N1. In the same way, the 2_8-th wordline WL28 may be electrically connected to the 3_8-th wordline WL38 disposed at substantially the same height through an eighth node N8, and the 2_8-th wordline WL28 and the 3_8-th wordline WL38 may activated together through the eighth node N8.

The memory cell MC may include a transistor TR and a capacitor CAP, and may have a 1T1C structure. A gate of the transistor TR may be connected to one of the plurality of wordlines WL21 to WL28 and WL31 to WL38, and source of a memory the cell transistor MCT may be connected to one of the plurality of bitlines BL11 to BL14 and BL21 to BL24. In some implementations, the capacitor CAP may correspond to the information storage element DS of FIG. 1 to FIG. 5, and a drain of the transistor TR may be connected to a first electrode of the capacitor CAP. A second electrode of the capacitor CAP may be connected to the ground wire PP of FIG. 1 to FIG. 5.

According to the semiconductor memory device, through the above-described connection of circuit elements, the memory cell array 100a increasing the number of the simultaneously driven memory cells and improving the RC delay performance may be provided.

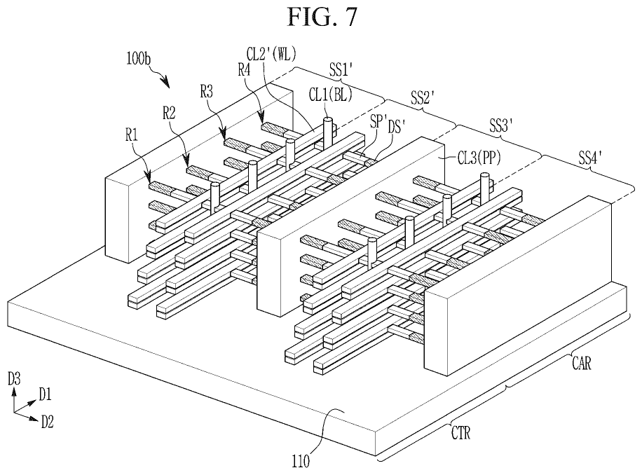

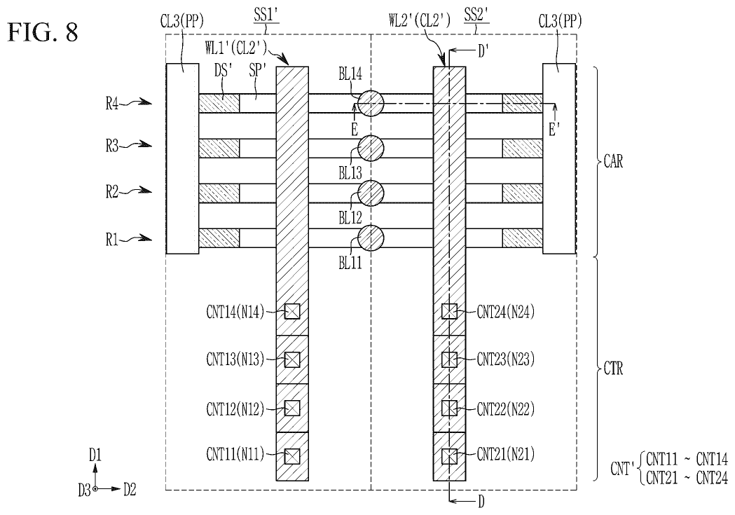

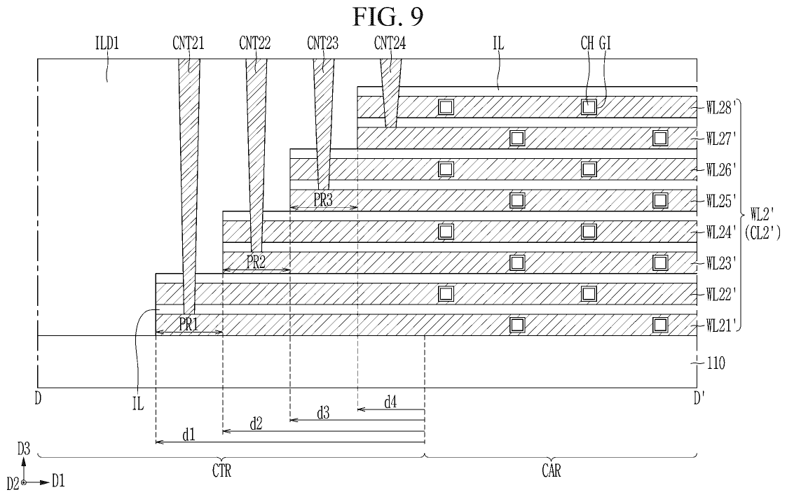

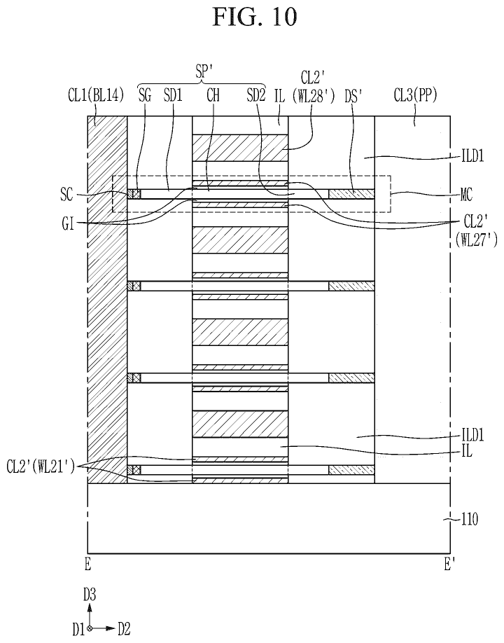

FIG. 7 is a perspective view showing a portion of an example of the semiconductor memory device. FIG. 8 is an example top plan view showing a portion of the stacking structures of FIG. 7. FIG. 9 is an example cross-sectional view taken along line D-D′ of FIG. 8. FIG. 10 is an example cross-sectional view taken along line E-E′ of FIG. 8. Specifically, FIG. 8 is a top plan view showing the first and second stacking structures SS1′ and SS2′ of a memory cell array 100b.

The memory cell array 100b of FIG. 7 to FIG. 10 may correspond to the memory cell array 100a of FIG. 1 to FIG. 5. For ease of description, the memory cell array 100b will be described focusing on the difference from the memory cell array 100a of FIG. 1 to FIG. 5.

Referring to FIG. 7 to FIG. 10, the semiconductor memory device may include the memory cell array 100b. The memory cell array 100b may include the plurality of bitlines BL extending along the third direction D3, the plurality of wordlines WL stacked along the third direction D3 and extending along the first direction D1, and the memory cell MC arranged at a location where the plurality of bitlines BL and the plurality of wordlines WL cross each other in a direction diagonal to the first and third directions D1 and D3 and connected to the plurality of bitlines BL and the plurality of wordlines WL.

Each of the plurality of first conductive lines CL1 may be disposed adjacent to a semiconductor pattern SP′ of the first to fourth columns R1 to R4 corresponding thereto, respectively, and electrically connected to the first to fourth stacking structures SS1′ to SS4′, and without being limited thereto, each of the first conductive line CL1 may directly contact the semiconductor pattern SP of the first to fourth columns R1 to R4 corresponding thereto.

Each of the first to fourth stacking structures SS1′ to SS4′ may include a plurality of semiconductor patterns SP′, a plurality of second conductive lines CL2′, and a plurality of information storage elements DS′. The first to fourth stacking structures SS1′ to SS4′, the plurality of semiconductor patterns SP′, the plurality of second conductive lines CL2′, and the plurality of information storage elements DS′ may correspond to the first to fourth stacking structures SS1 to SS4, the plurality of semiconductor patterns SP, the plurality of second conductive lines CL2, and the plurality of information storage elements DS of FIG. 1 to FIG. 5, respectively. For ease of description, description on the first to fourth stacking structures SS1′ to SS4′, the plurality of semiconductor patterns SP′, the plurality of second conductive lines CL2′, and the plurality of information storage elements DS′ will be made focusing on differences from the first to fourth stacking structures SS1 to SS4, the plurality of semiconductor patterns SP, the plurality of second conductive lines CL2, and the plurality of information storage elements DS.

Each of the first to fourth stacking structures SS1′ to SS4′ may include the semiconductor pattern SP′ of the first to fourth columns R1 to R4 on the cell array region CAR of the substrate 110. Each of the first to fourth columns R1 to R4 may include the plurality of semiconductor patterns SP′ that are vertically stacked and planarly overlapping with each other. The plurality of semiconductor patterns SP′ may be arranged in a direction diagonal to the first and third directions D1 and D3, at a location where the first conductive line CL1 and the plurality of second conductive lines CL2′ cross each other. For example, although the number of the semiconductor pattern SP′ of each of the first to fourth columns R1 to R4 is shown as 4 as an example, it is not particularly limited thereto.

The plurality of second conductive lines CL2′ may include a first wordline WL1′ included in the first stacking structure SS1′ and extending in the first direction and a second wordline WL2′ included in the second stacking structure SS2′ and extending in the first direction.

When the arrangement of the semiconductor pattern SP′ is described taking the 1_3-th to 1_4-th bitlines BL13 and BL14 and the second wordline WL2′ included in the second conductive line CL2′ as an example, the semiconductor pattern SP′ may be disposed to extend in the second direction D2, at a location where the 2_2-th wordline W22′, the 2_4-th wordline W24′, the 2_6-th wordline W26′, and the 2_8-th wordline W28′ cross the 1_3-th bitline BL13, which is a third column R3. The semiconductor pattern SP′ may not be disposed at a location where the 2_1-th wordline W21′, the 2_3-th wordline W23′, the 2_5-th wordline W25′, and the 2_7-th wordline W27′ cross 1_3-th bitline BL13, which is the third column R3.

In addition, the semiconductor pattern SP′ may be disposed to extend in the second direction D2, at a location where the 2_1-th wordline W21′, the 2_3-th wordline W23′, the 2_5-th wordline W25′, and the 2_7-th wordline W27′ cross the 1_4-th bitline BL14, which is the fourth column R4. The semiconductor pattern SP′ may not be disposed at a location where the 2_2-th wordline W22′, the 2_4-th wordline W24′, the 2_6-th wordline W26′, and the 2_8-th wordline W28′ cross the 1_4-th bitline BL14, which is the fourth column R4.

Therefore, the semiconductor pattern SP′ disposed in the fourth column R4 and disposed at substantially the same height as a 2_1-th wordline WL21′ may be disposed adjacent in the third direction to the semiconductor pattern SP′ disposed in the fourth column R4 and disposed at substantially the same height as a 2_3-th wordline WL23′. The semiconductor pattern SP′ disposed in the fourth column R4 and disposed at substantially the same height as the 2_1-th wordline WL21′ may be disposed adjacent in the first direction D1 to the semiconductor pattern SP′ disposed in a second column R2 and disposed at substantially the same height as the 2_1-th wordline WL21′.

The second conductive line CL2′ may extend from the cell array region CAR of the substrate 110 to the contact region CTR, in the unit of two conductive lines adjacent in the third direction D3. Each of the plurality of second conductive lines CL2′ may have a stepped structure on the contact region CTR of the substrate 110.

The lengths of the plurality of second conductive lines CL2′ stacked on the contact region CTR in the first direction D1 may be in the same length or longer as it is closer to the upper surface of the substrate 110. Referring to FIG. 9, the plurality of second conductive lines CL2′ may extend in the opposite direction of the first direction D1 to be in the same length or longer as it is closer to the substrate 110. The second conductive line CL2 disposed in a lower portion may extend to the same extent as or protrude further than a sidewall of the second conductive line CL2 disposed in an upper portion.

The first wordline WL1′ may be vertically stacked in the third direction D3, and vertically spaced apart from each other by the plurality of insulation layers IL. In the same way, the second wordline WL2′ may be vertically stacked in the third direction D3, and vertically spaced apart from each other by the plurality of insulation layers IL. The insulation layer IL may be interposed between a pair of first wordlines WL1′ perpendicularly adjacent to each other and between a pair of second wordlines WL2′ perpendicularly adjacent to each other. Since it is obvious that the description on the second wordline WL2′ below may be applied to the first wordline WL1′, the description below will be made based on the second wordline WL2′.

As an example, the second wordline WL2′ may include 2_1-th to 2_8-th wordlines WL21′ to WL28′ stacked in the third direction D3 from the substrate 110. The 2_1-th to 2_8-th wordlines WL21′ to WL28′ may be vertically spaced apart from each other by the plurality of insulation layers IL.

The 2_1-th to 2_8-th wordlines WL21′ to WL28′ may extend from the cell array region CAR of the substrate 110 to the contact region CTR, in the unit of two wordlines adjacent in the third direction D3. The second wordline WL2′ may have a stepped structure in the unit of two wordlines adjacent in the third direction D3, on the contact region CTR of the substrate 110. A length of the second wordline WL2′ stacked on the contact region CTR in the first direction D1 may be in the same length or longer as it is closer to the upper surface of the substrate 110. Referring to FIG. 8 and FIG. 9, the second wordline WL2 may extend in the opposite direction of the first direction D1 to be in the same length or longer as it is closer to the substrate 110. The second wordline WL2 disposed in a lower portion may extend to the same extent as or protrude further than a sidewall of the second wordline WL2 disposed in an upper portion.

Taking FIG. 9 as an example, among the stacked second wordlines WL2, the 2_1-th wordline WL21′ in the lowermost portion and a 2_2-th wordline WL22′ adjacent thereto in the third direction D3 may extend to the same extent in the opposite direction of the first direction D1, and may extend by first distance d1 in the opposite direction of the first direction D1 based on the cell array region CAR. Each of the 2_1-th wordline WL21′ and the 2_2-th wordline WL22′ adjacent thereto may include a first common protrusion region PR1 that protrudes in the opposite direction of the first direction D1 further than the sidewall of the 2_3-th and 2_4-th wordlines WL23′ and WL24′.

The 2_3-th wordline WL23′ and a 2_4-th wordline WL24′ adjacent thereto in the third direction D3 may extend to the same extent in the opposite direction of the first direction D1, and may extend by second distance d2 in the opposite direction of the first direction D1 based on the cell array region CAR. Each of the 2_3-th wordline WL23′ and the 2_4-th wordline WL24′ adjacent thereto may include a second common protrusion region PR2 that protrudes in the opposite direction of the first direction D1 further than the sidewall of the 2_5-th and 2_6-th wordlines WL25′ and WL26′.

A 2_5-th wordline WL25′ and a 2_6-th wordline WL26′ adjacent thereto in the third direction D3 may extend to the same extent in the opposite direction of the first direction D1, and may extend by third distance d3 in the opposite direction of the first direction D1 based on the cell array region CAR. Each of the 2_5-th wordline WL25′ and the 2_6-th wordline WL26′ adjacent thereto may include a third common protrusion region PR3 that protrudes in the opposite direction of the first direction D1 further than the sidewall of the 2_7-th and 2_8-th wordlines WL27′ and WL28′.

A 2_7-th wordline WL27′ and a 2_8-th wordline WL28′ adjacent thereto in the third direction D3 may extend to the same extent in the opposite direction of the first direction D1, and may extend by fourth distance d4 in the opposite direction of the first direction D1 based on the cell array region CAR.

In the contact region CTR, first to third common protrusion regions PR1 to PR3 and an extension region of the 2_7-th and 2_8-th wordlines WL27′ and WL28′ may be the connection pad on which a contact CNT′ lands. The contact CNT′ may extend in the opposite direction of the third direction D3, and land on a corresponding region that protrudes or extends. Although drawings illustrate that the second wordline WL2′ is spaced apart in the third direction D3 by the plurality of insulation layers IL, in the contact region CTR, each of the 2_1-th to 2_2-th wordlines WL21′ and WL22′, the 2_3-th to 2_4-th wordlines WL23′ and WL24′, the 2_5-th to 2_6-th wordlines WL25′ and WL26′, and the 2_7-th to 2_8-th wordlines WL27′ and WL28′ may be connected in the third direction D3 by a conductive layer.

The contact CNT′ may include 1_1-th to 1_4-th contacts CNT11 to CNT14 corresponding to the first wordline WL1′ and 2_1-th to 2_4-th contacts CNT21 to CNT24 corresponding to the second wordline WL2′. Since it is obvious that the description on the second wordline WL2′ and the 2_1-th to 2_4-th contacts CNT21 to CNT24 may be applied to the first wordline WL1′ and the 1_1-th to 1_4-th contacts CNT11 to CNT14, the description below will be made based on the second wordline WL2′ and the 2_1-th to 2_4-th contacts CNT21 to CNT24.

Each of the 2_1-th to 2_4-th contacts CNT21 to CNT24 may land on the first to third common protrusion regions PR1 to PR3 and extension regions of the 2_7-th and 2_8-th wordlines WL27′ and WL28′, respectively.

As an example, the 2_1-th contact CNT21 may extend in the opposite direction of the third direction D3 and land on the first common protrusion region PR1. The 2_1-th contact CNT21 may penetrate the 2_2-th wordline W22′ to contact the 2_1-th wordline W21′, thereby being electrically connected to the 2_1-th wordline W21′ and the 2_2-th wordline W22′. In the same way, the 2_2-th contact CNT22 may extend in the opposite direction of the third direction D3 and land on the second common protrusion region PR2. The 2_2-th contact CNT22 may penetrate the 2_4-th wordline W24′ to contact the 2_3-th wordline W23′, and the 2_3-th wordline W23′ thereby being electrically connected to the 2_4-th wordline W24′. The 2_3-th contact CNT23 may extend in the opposite direction of the third direction D3 and land on the third common protrusion region PR3. The 2_3-th contact CNT23 may penetrate the 2_6-th wordline W26′ to contact the 2_5-th wordline W25′, and the 2_5-th wordline W25′ thereby being electrically connected to the 2_6-th wordline W26′.

The 2_4-th contact CNT24 may extend in the opposite direction of the third direction D3, and may land on the extension region of the 2_7-th and 2_8-th wordlines WL27′ and WL28′ in the contact region CTR. The 2_4-th contact CNT24 may penetrate the 2_8-th wordline W28′ to contact the 2_7-th wordline W27′, and the 2_7-th wordline W27′ thereby being electrically connected to the 2_8-th wordline W28′.

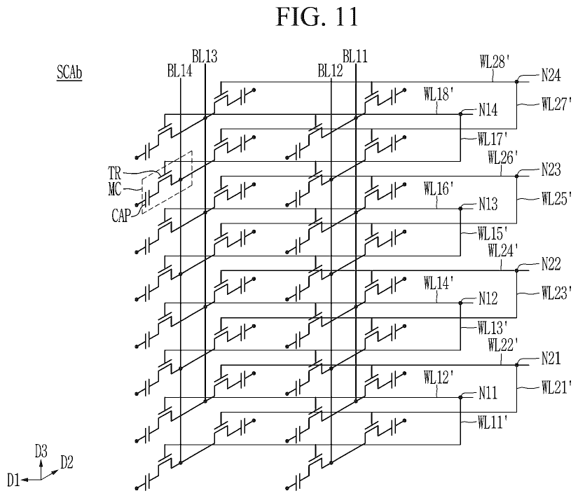

The 1_1-th to 1_4-th contacts CNT11 to CNT14 and the 2_1-th to 2_4-th contacts CNT21 to CNT24 may correspond to 1_1-th to 1_4-th nodes N11 to N14 and 2_1-th to 2_4-th nodes N21 to N24 of FIG. 11 to be described later. Each of the 2_1-th to 2_4-th contacts CNT21 to CNT24 may be a common node connected to the 2_1-th and 2_2-th wordlines WL21′ and WL22′, the 2_3-th and 2_4-th wordlines WL23′ and WL24′, the 2_5-th and 2_6-th wordlines WL25′ and WL26′, and the 2_7-th and 2_8-th wordlines WL27′ and WL28′ corresponding thereto. Through the above-described structure of the common protrusion region and the contact, wordlines spaced apart from each other in the cell array region CAR may be activated together.

Although not shown in FIG. 7 to FIG. 10, each of the third and fourth stacking structures SS3′ and SS4′ may include a wordline corresponding to the first and second wordlines WL1′ and WL2′ of the first and second stacking structures SS1′ and SS2′.

Each of the first to fourth stacking structures SS1′ to SS4′ may further include the plurality of information storage elements DS′ that are vertically stacked. The plurality of information storage elements DS′ that are vertically stacked may be vertically spaced apart from each other by the first interlayer insulating layer ILD1. The plurality of information storage elements DS′ may extend in the second direction D2 from the semiconductor patterns SP′, respectively.

The plurality of information storage elements DS′ may directly contact the plurality of semiconductor patterns SP′. For example, the information storage elements DS′ may be located at substantially the same level as the semiconductor patterns SP′, respectively. The information storage elements DS′ may be connected to the second extrinsic region SD2 of the semiconductor patterns SP′, respectively. For example, although the number of the information storage element DS′ of each of the first to fourth columns R1 to R4 is shown as 4 as an example, it is not particularly limited thereto.

The semiconductor pattern SP′ and the information storage element DS′ disposed between the first conductive line CL1 and the third conductive line CL3, and penetrating the second conductive line CL2′ may be driven as the memory cell MC.

According to the semiconductor memory device, through the above-described structure of the common protrusion region and the contact, the number of the simultaneously driven memory cells may be increased and the wiring length with respect to one wordline may be reduced. According to the reduced wiring length, the wire resistance and the parasitic capacitor between wordlines stacked in the third direction D3 may be reduced. According to the semiconductor memory device, through the improved wire resistance and parasitic capacitor, the RC delay caused by wordlines as the memory cells are densely disposed may be improved.

FIG. 11 is a circuit diagram showing an example of the memory cell array included in the semiconductor memory device. Specifically, the circuit diagram of FIG. 11 is a circuit diagram showing a sub-cell array SCAb that corresponds to the first to the second stacking structures SS1′ and SS2′ of FIG. 7 to FIG. 10, and is a portion of the memory cell array 100b.

Referring to FIG. 7 to FIG. 11, the memory cell array 100b may include the sub-cell array SCAb. The sub-cell array SCAb may be arranged along the second direction D2.

The sub-cell array SCAb may include the plurality of bitlines BL11 to BL14, a plurality of wordlines WL11′ to WL18′ and WL21′ to WL28′, and the plurality of memory cells MC. The plurality of memory cells MC may correspond to the plurality of memory cells MC of FIG. 6.

Each of the plurality of bitlines BL11 to BL14 may extend in the third direction D3, perpendicularly to the substrate, and may be conductive patterns (e.g., metal line) disposed on the substrate. The plurality of bitlines BL11 to BL14 and BL21 to BL24 may include the 1_1-th to 1_4-th bitlines BL11 to BL14 and the plurality of bitlines BL11 to BL14 and BL21 to BL24. The 1_1-th to 1_4-th bitlines BL11 to BL14 may be spaced apart from each other in the first direction D1, and the 2_1-th to 2_4-th bitlines BL21 to BL24 may be spaced apart from each other in the first direction D1. In addition, the 1_1-th to 1_4-th bitlines BL11 to BL14 may be spaced apart from the 2_1-th to 2_4-th bitlines BL21 to BL24 the second direction D2, respectively.

The plurality of wordlines WL11′ to WL18′ and WL21′ to WL28′ may be conductive patterns (e.g., metal line) extending in the first direction D1 on the substrate. The plurality of wordlines WL11′ to WL18′ and WL21′ to WL28′ may include 1_1-th to 1_8-th wordlines WL11′ to WL18′ and the 2_1-th to 2_8-th wordlines WL21′ to WL28′. The 1_1-th to 1_8-th wordlines WL11′ to WL18′ may be stacked perpendicularly to the substrate, and may be spaced apart from each other in the third direction D3. The 2_1-th to 2_8-th wordlines WL21′ to WL28′ may be stacked perpendicularly to the substrate, and may be spaced apart from each other in the third direction D3. In addition, each of the 1_1-th to 1_8-th wordlines WL11′ to WL18′ may be spaced apart from each of the 2_1-th to 2_8-th wordlines WL21′ to WL28′ disposed at substantially the same height in the second direction D2.

In the 1_1-th to 1_8-th wordlines WL11′ to WL18′, wordlines adjacent in the third direction D3 may be electrically connected through common node, and may be activated together. Taking FIG. 11 as an example, the 1_1-th and 1_2-th wordlines WL11′ and WL12′ may be electrically connected through a 1_1-th node N11′, which is a common node, and may be activated together. The 1_3-th and 1_4-th wordlines WL13′ and WL14′ may be electrically connected through a 1_2-th node N12′, which is a common node, and may be activated together. The 1_5-th and 1_6-th wordlines WL15′ and WL16′ may be electrically connected through a 1_3-th node N13′, which is a common node, and may be activated together. The 1_7-th and 1_8-th wordlines WL17′ and WL18′ may be electrically connected through a 1_4-th node N14′, which is a common node, and may be activated together.

In the 2_1-th to 2_8-th wordlines WL21′ to WL28′, wordlines adjacent in the third direction D3 may be electrically connected through common node, and may be activated together. Taking FIG. 11 as an example, the 2_1-th and 2_2-th wordlines WL21′ and WL22′ may be electrically connected through a 2_1-th node N21′, which is a common node, and may be activated together. The 2_3-th and 2_4-th wordlines WL23′ and WL24′ may be electrically connected through a 2_2-th node N22′, which is a common node, and may be activated together. The 2_5-th and 2_6-th wordlines WL25′ and WL26′ may be electrically connected through a 2_3-th node N23′, which is a common node, and may be activated together. The 2_7-th and 2_8-th wordlines WL27′ and WL28′ may be electrically connected through a 2_4-th node N24′, which is a common node, and may be activated together.

At a location where the plurality of bitlines BL11 to BL14 and the plurality of wordlines WL11′ to WL18′ and WL21′ to WL28′ cross each other, the memory cell MC may be arranged in a direction diagonal to the first and third directions D1 and D3.

When the arrangement of the memory cell MC is described taking the 1_3-th to 1_4-th bitlines BL13 and BL14 and the 2_1-th to 2_8-th wordlines WL21′ to WL28′ as an example, the memory cell MC may be disposed at a location where the 2_2-th wordline W22′, the 2_4-th wordline W24′, the 2_6-th wordline W26′, and the 2_8-th wordline W28′ and 1_3-th bitline BL13 cross each other. The memory cell MC may not be disposed at a location where the 2_1-th wordline W21′, the 2_3-th wordline W23′, the 2_5-th wordline W25′, and the 2_7-th wordline W27′ and 1_3-th bitline BL13 cross each other.

In addition, the memory cell MC may be disposed at a location where the 2_1-th wordline W21′, the 2_3-th wordline W23′, the 2_5-th wordline W25′, and the 2_7-th wordline W27′ and the 1_4-th bitline BL14 cross each other. The memory cell MC may not be disposed at a location where the 2_2-th wordline W22′, the 2_4-th wordline W24′, the 2_6-th wordline W26′, and the 2_8-th wordline W28′ and the 1_4-th bitline BL14 cross each other.

According to the semiconductor memory device, through the above-described connection of the circuit elements, the memory cell array 100b increasing the number of the simultaneously driven memory cells and improving the RC delay performance may be provided.

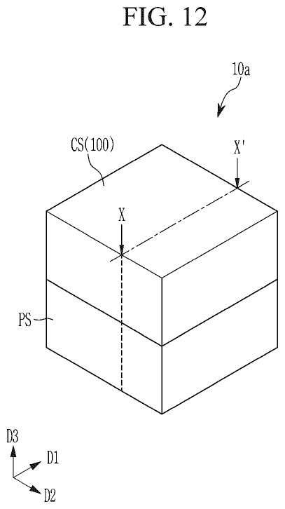

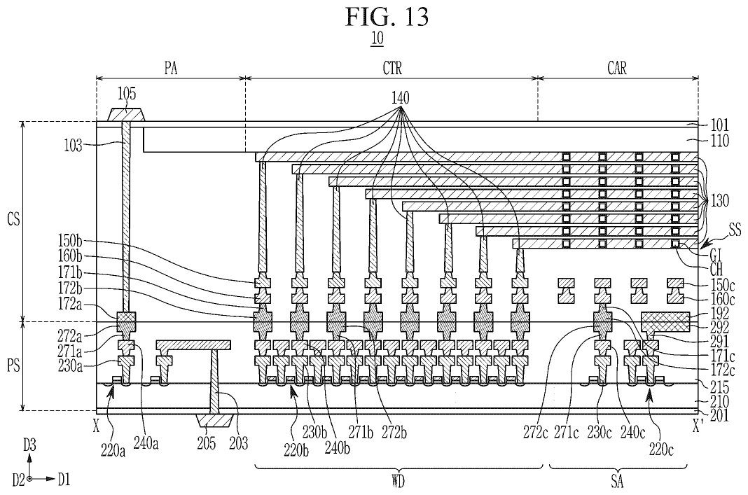

FIG. 12 is a perspective view showing an example of the semiconductor memory device. FIG. 13 is an example cross-sectional view taken along line X-X′ of FIG. 12.

A semiconductor memory device 10a may be a chip-to-chip (C2C) structure. The semiconductor memory device 10a may include a cell array structure CS, and a peripheral circuit structure PS. The cell array structure CS and the peripheral circuit structure PS may be stacked in the third direction D3, such that the cell array structure CS and the peripheral circuit structure PS may overlap with each other at least partially in the third direction D3. It may be a Cell-on-Peri (COP) structure in which the cell array structure CS is disposed above the peripheral circuit structure PS based on the third direction D3. The cell array structure CS may correspond to the memory cell array 100. The memory cell array 100 may be the memory cell arrays 100a and 100b of FIG. 1 to FIG. 11.

The cell array structure CS of the semiconductor memory device 10a may correspond to the memory cell array 100. The memory cell array 100 may be the memory cell arrays 100a and 100b of FIG. 1 to FIG. 11. Each of the cell array structure CS of the semiconductor memory device 10a, and the peripheral circuit structure PS may include an external pad bonding area PA, the contact region CTR, and the cell array region CAR. Each of the contact region CTR and the cell array region CAR may correspond to the contact region CTR and the cell array region CAR of FIG. 2 to FIG. 5 and FIG. 7 to FIG. 11, respectively.

The peripheral circuit structure PS may include a first substrate 210, a first interlayer insulating layer 215, a plurality of circuit elements 220a, 220b, and 220c formed on the first substrate 210, first metal layers 230a, 230b, and 230c connected to the plurality of circuit elements 220a, 220b, and 220c, respectively, second metal layers 240a, 240b, and 240c formed on the first metal layers 230a, 230b, and 230c. In some implementations, the first metal layers 230a, 230b, and 230c may be formed of tungsten having relatively high resistance, and the second metal layers 240a, 240b, and 240c may be formed of copper having relatively low resistance.

Although drawings only illustrate the first metal layers 230a, 230b, and 230c and the second metal layers 240a, 240b, and 240c, it is not limited thereto, and at least one metal layer may be further formed on the second metal layers 240a, 240b, and 240c. At least some of one or more metal layers that are formed on the second metal layers 240a, 240b, and 240c may be formed of a material having resistance lower than that of copper forming the second metal layers 240a, 240b, and 240c, such as aluminum, etc.

The first interlayer insulating layer 215 may be placed on the first substrate 210 to cover the plurality of circuit elements 220a, 220b, and 220c, the first metal layer 230a, 230b, and 230c, and the second metal layer 240a, 240b, and 240c, and include an insulating material such as silicon oxide, silicon nitride, etc.

Lower bonding metals 271b and 272b may be formed on a second metal layer 240b of the contact region CTR. In the contact region CTR, the lower bonding metals 271b and 272b of the peripheral circuit structure PS may be electrically connected to upper bonding metals 171b and 172b of the cell array structure CS by a bonding method, and the lower bonding metals 271b and 272b and the upper bonding metals 171b and 172b may be formed of aluminum, copper, tungsten, or the like.

The cell array structure CS may provide at least one sub-cell array. In the cell array structure CS, a plurality of conductive lines 130 may be stacked along a direction (i.e., the third direction D3) perpendicular to a second substrate 110 and an upper surface of the second substrate 110.

In some implementations, the plurality of conductive lines 130 may include the plurality of wordlines. The plurality of conductive lines 130 may be a plurality of second conductive lines CL2 and CL2′ of FIG. 1 to FIG. 5 and FIG. 7 to FIG. 10.

In the cell array region CAR, a plurality of channel regions CH may extend in the second direction D2 and penetrate the plurality of conductive lines 130. Although not shown in the drawings, in the cell array region CAR, the information storage element extending from sidewalls of the plurality of channel regions CH to the second direction D2, or the like, may be provided. In some implementations, through the arrangement of the plurality of conductive lines 130 and the plurality of channel regions CH, the memory cell may be disposed in the same form as the sub-cell arrays SCAa and SCAb of FIG. 6 and FIG. 11. Although not shown in the drawings, the plurality of channel regions CH may be electrically connected to a first metal layer 150c and a second metal layer 160c. For example, the first metal layer 150c may be a bitline contact, and the second metal layer 160c may be a bitline. In some implementations, the second metal layer 160c may be a global bitline that extends along the second direction D2 parallel to the upper surface of the second substrate 110.

A region where the plurality of channel regions CH, the second metal layer 160c, or the like are disposed may be defined as the cell array region CAR. The second metal layer 160c may be electrically connected to the circuit elements 220c included in a sense amplifier circuit SA of the peripheral circuit structure PS in the cell array region CAR. For example, the second metal layer 160c may be connected to the upper bonding metals 171c and 172c of the cell array structure CS. Accordingly, the sense amplifier circuit SA may be electrically connected to the second metal layer 160c through the bonding metals 171c, 172c, 271c, and 272c. In some implementations, at least some of the circuit elements 220c of the sense amplifier circuit SA may be disposed to overlap with the bonding metals 171c, 172c, 271c, and 272c and the cell array region CAR in the third direction D3. In some implementations, the sense amplifier circuit SA may sense and amplify the voltage stored in the memory cell, and read data stored in the memory cell.

Also, in the bonding area where the cell array structure CS and the peripheral circuit structure PS are in contact, the upper bonding metal 171c and 172c of the sense amplifier circuit SA may be in contacted and electrically connected by a bonding method with the lower bonding metal 271c and 272c, which are connected to the circuit elements 220c of the page buffer 14.

In the contact region CTR, the plurality of conductive lines 130 may extend along the first direction D1 parallel to the upper surface of the second substrate 110, and may be connected to a plurality of cell contact plugs 140. At least some of the plurality of cell contact plugs 140 may extend in the first direction D1 to different lengths, and may be connected to the plurality of conductive lines 130 at the connection pad providing a landing location with respect to the cell contact plug. The plurality of cell contact plugs 140 may be contacts CNT and CNT′ of FIG. 2 to FIG. 5 and FIG. 8 to FIG. 10. A first metal layer 150b and a second metal layer 160b may be sequentially connected to an upper portion of the plurality of cell contact plugs 140 connected to the plurality of conductive lines 130. The plurality of cell contact plugs 140 may be connected to the peripheral circuit structure PS through the upper bonding metals 171b and 172b of the cell array structure CS and the lower bonding metals 271b and 272b of the peripheral circuit structure PS, in the contact region CTR.

The plurality of cell contact plugs 140 may be electrically connected to the circuit elements 220b included in a wordline driver WD in the peripheral circuit structure PS. In some implementations, at least some of the circuit elements 220b providing the wordline driver WD may planarly overlap with the plurality of cell contact plugs 140. For example, the plurality of cell contact plugs 140 may be connected to the upper bonding metals 171b and 172b of the cell array structure CS. Accordingly, the wordline driver WD may be electrically connected to the plurality of cell contact plugs 140 through the bonding metals 171b, 172b, 271b, and 272b. In some implementations, at least some of the circuit elements 220b of the plurality of cell contact plugs 140 may be disposed to overlap with the bonding metals 171b, 172b, 271b, and 272b and the contact region CTR in the third direction D3. In some implementations, the wordline driver WD may provide the operating voltage to the memory cell through the plurality of conductive lines 130 and the plurality of cell contact plugs 140.

Input/output pads 105 and 205 may be disposed in the external pad bonding area PA. A lower insulation layer 201 that covers a lower surface of the first substrate 210 may be formed in a lower portion of the first substrate 210, and a first input/output pad 205 may be formed on the lower insulation layer 201. The first input/output pad 205 may be connected to at least one of the plurality of circuit elements 220a, 220b, and 220c disposed in the peripheral circuit structure PS through a first input/output contact plug 203, and may be separated from the first substrate 210 by the lower insulation layer 201. In addition, a side surface insulation layer may be disposed between the first input/output contact plug 203 and the first substrate 210, such that the first input/output contact plug 203 and the first substrate 210 may be electrically separated.

An upper insulation layer 101 that covers the upper surface of the second substrate 110 may be formed in an upper portion of the second substrate 110, and a second input/output pad 105 may be disposed on the upper insulation layer 101. The second input/output pad 105 may be connected to at least one of the plurality of circuit elements 220a, 220b, and 220c disposed in the peripheral circuit structure PS through a second input/output contact plug 103, bonding metals 172a, 271a, and 272a, and first and second metal layers 230a and 240b.

In some implementations, the second substrate 110 or the like may not be disposed in a region where the second input/output contact plug 103 is disposed. In addition, the second input/output pad 105 may be disposed to planarly non-overlap based on the plurality of conductive lines 130 and the third direction D3. The second input/output contact plug 103 may be separated from the second substrate 110 in a direction parallel to the upper surface of the second substrate 110, and may penetrate an interlayer insulating layer of the cell array structure CS, to be connected to the second input/output pad 105.

In some implementations, the first input/output pad 205 and the second input/output pad 105 may be selectively formed. For example, the semiconductor memory device 10a may only include the first input/output pad 205 disposed on an upper portion of the first substrate 210, or may only include the second input/output pad 105 disposed in the upper portion of the second substrate 110. Alternatively, the semiconductor memory device 10a may include both of the first input/output pad 205 and the second input/output pad 105.

In each of the external pad bonding area PA and the cell array region CAR included in each of the cell array structure CS and the peripheral circuit structure PS, the metal pattern of the uppermost metal layer may be present as a dummy pattern, or the uppermost metal layer may be empty.

In the external pad bonding area PA, corresponding to the lower metal pattern formed in the uppermost metal layer of the peripheral circuit structure PS, an upper metal pattern of the same type as the lower metal pattern of the peripheral circuit structure PS may be formed in the upper metal layer of the cell array structure CS.

The lower bonding metals 271b and 272b may be formed on the second metal layer 240b of the contact region CTR. In the contact region CTR, the lower bonding metals 271b and 272b of the peripheral circuit structure PS may be in contact with and electrically connected to the upper bonding metals 171b and 172b of the cell array structure CS by a bonding method.

In addition, in the cell array region CAR, an upper metal pattern 192 in the same shape as the lower metal pattern 292 may be formed in an uppermost metal layer of the cell array structure CS, to correspond to a lower metal pattern 292 formed in the uppermost metal layer of the peripheral circuit structure PS. The contact may not be formed on the upper metal pattern 192 formed in the uppermost metal layer of the cell array structure CS.

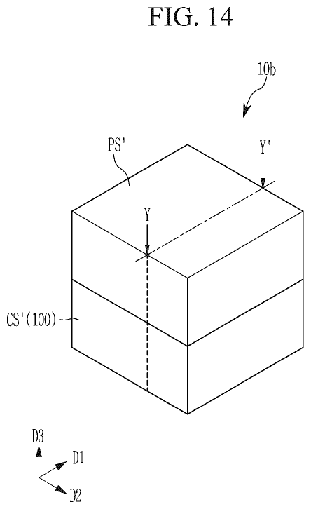

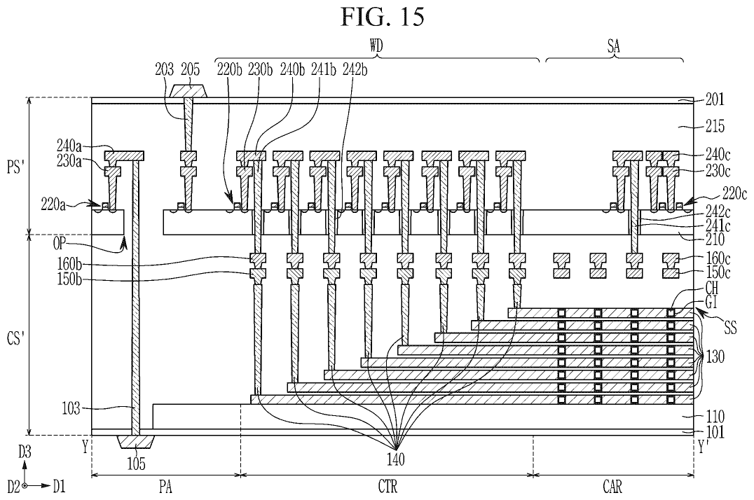

FIG. 14 is a perspective view showing an example of the semiconductor memory device. FIG. 15 is an example cross-sectional view taken along line Y-Y′ of FIG. 14. A semiconductor memory device 10b may correspond to the semiconductor memory device 10a of FIG. 12 and FIG. 13. Hereinafter, for ease of description, the semiconductor memory device 10b of FIG. 14 and FIG. 15 will be described focusing on differences from the semiconductor memory device 10a of FIG. 12 and FIG. 13.

Referring to FIG. 14 and FIG. 15, the semiconductor memory device 10b may include a cell array structure CS′, and a peripheral circuit structure PS′. The cell array structure CS′, and the peripheral circuit structure PS′ may correspond to the cell array structure CS, and the peripheral circuit structure PS of FIG. 12 and FIG. 13, respectively.

It may be a Peri-on-Cell (POC) structure in which the peripheral circuit structure PS′ is disposed above the cell array structure CS′ based on the third direction D3.

When compared to the semiconductor memory device 10a of FIG. 12 and FIG. 13, in the semiconductor memory device 10b, the lower bonding metals 271b to 271c and 272a to 272c and the lower metal pattern 292 of the semiconductor memory device 10a and upper bonding metals 171a to 171c and 172a to 172c and the upper metal pattern 192 of the semiconductor memory device 10a are not disposed.

In addition, a plurality of circuit elements 220a, 220b, and 220cs formed in the first substrate 210 may be disposed between the second metal layers 240a, 240b, and 240c of the peripheral circuit structure PS′ and the second metal layers 160b and 160c of the cell array structure CS′.

Accordingly, the plurality of circuit elements 220a, 220b, and 220c of the peripheral circuit structure PS′ may be disposed above the second metal layers 160b and 160c of the cell array structure CS′ based on the third direction D3.

In some implementations, in the external pad bonding area PA, the first substrate 210 may include an opening OP. In some implementations, a first interlayer insulating layer 215 and a second interlayer insulating layer 115 may be in contact with each other through the openings OP. Second input/output contact plugs 103 may extend in the third direction D3 through the openings OP and pass through some portions of the second interlayer insulating layer 115 and the first interlayer insulating layer 215, thereby being electrically coupled to the second metal layers 240a of the external pad bonding area PA. In some implementations, the second input/output contact plug 103 may be electrically connected to the circuit elements 220a within the external pad bonding area PA.

In some implementations, a first through via 241b extending along the third direction D3 in the contact region CTR and penetrating a portion of first and second interlayer insulating layers 115 and 215 and the first substrate 210 may be disposed. A first side surface insulation layer 242b may be interposed between the first substrate 210 and the first through via 241b.

In the contact region CTR, the first through via 241b may extend in the third direction D3, and may be in contact with and electrically connected to the second metal layer 240b of the cell array structure CS′ and the second metal layer 160b of the peripheral circuit structure PS′. Through the first through via 241b, the plurality of cell contact plugs 140 and the circuit elements 220b included in the wordline driver WD may be electrically connected.

In some implementations, a second through via 241c extending along the third direction D3 in the cell array region CAR and penetrating a portion of the first and second interlayer insulating layers 115 and 215 and the first substrate 210 may be disposed. A second side surface insulation layer 242c may be interposed between the first substrate 210 and the second through via 241c.

In the cell array region CAR, the second through via 241c may extend in the third direction D3, and may be in contact with and electrically connected to a second metal layer 240c of the cell array structure CS′ and the second metal layer 160c of the peripheral circuit structure PS′. Through the second through via 241c, the second metal layer 160c and the circuit elements 220c included in the sense amplifier circuit SA may be electrically connected.

The first and second through vias 241b and 241c may include a conducting material. As an example, the conducting material may be one among a doped semiconductor material (doped silicon, doped germanium, or the like), a conductive metal nitride (titanium nitride, tantalum nitride, or the like), a metal (tungsten, titanium, tantalum, or the like), and a metal-semiconductor compound (tungsten silicide, cobalt silicide, titanium silicide, or the like).

The first and second side surface insulation layers 242b and 242c may be selected from the group consisting of a silicon oxide layer, a silicon nitride layer, a silicon oxide nitride layer, a carbon-containing silicon oxide layer, a carbon-containing silicon nitride layer, and a carbon-containing silicon oxide nitride layer.

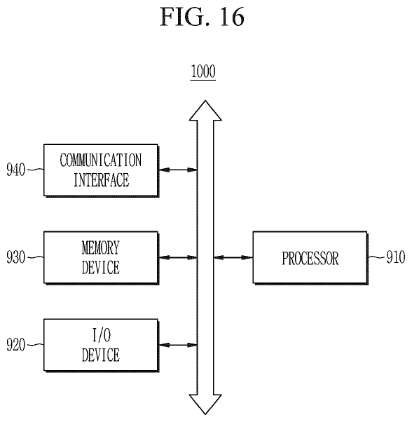

FIG. 16 is a block diagram showing an example of an electronic device.

Referring to FIG. 16, an electronic device 1000 may include a PDA, a laptop computer, a portable computer, a web tablet, a wireless phone, a mobile phone, a digital music player, a wired/wireless electronic device, etc., but is not limited thereto. The electronic device 1000 may include a processor 910, an input/output device (920, e.g., a keypad, a keyboard and/or a display), a memory device 930, and a wireless interface 940.

The processor 910 may be implemented as a hardware-like processing circuit including logic circuits, a hardware/software combination such as a processor execution software, or a combination thereof. For example, the processor 910 may more specifically include, but is not limited to, a central processing unit (CPU), a microprocessor, a digital signal processor, a micro controller or other logic device. The logic device may have a function similar to one among a microprocessor, a digital signal processor, and a micro controller.

The memory device 930 may store instructions to be executed by the processor 910, for example. Additionally, the memory device 930 may also be used to store a user data. The memory device 930 may include a plurality of memory cells. The plurality of memory cells may be the memory cell described with reference to FIG. 1 to FIG. 15, and the memory device 930 may include a 3-dimensional DRAM memory with improved integration and electrical performance.

The electronic device 1000 may use the communication interface 940 to transmit a data to or receive a data from a wireless communication network that communicates with wireless frequency (RF) signals. For example, the communication interface 940 may include an antenna or a wireless transceiver. The electronic device 1000 can be used for communication interface protocols such as third generation communication systems (e.g., CDMA, GSM, NADC, E-TDMA, WCDMA and/or CDMA2000).

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described in connection with the disclosed implementations, it is to be understood that the present disclosure is not limited to the disclosed implementations. On the contrary, it is intended to cover various modifications and equivalent arrangements included within the spirit and scope of the appended claims.

1. A semiconductor memory device comprising:
a first conductive line extending in a first direction perpendicular to a substrate;
a first gate electrode extending in a second direction on the substrate, the second direction crossing the first direction;
a first semiconductor pattern extending from the first conductive line to the first gate electrode;
a second gate electrode spaced apart from the first gate electrode on the substrate and extending in the second direction; and
a contact extending in the first direction and electrically connected with the first gate electrode and the second gate electrode.

2. The semiconductor memory device of claim 1, comprising a third gate electrode disposed between the first gate electrode and the substrate and overlapping with at least a portion of the first gate electrode in the first direction,
wherein an interlayer insulating layer is disposed between the first gate electrode and the third gate electrode.

3. The semiconductor memory device of claim 2, wherein a protrusion of the third gate electrode in the second direction is greater than a protrusion of the first gate electrode in the second direction.

4. The semiconductor memory device of claim 2, comprising a first information storage element disposed between the first semiconductor pattern and a ground wire,
wherein a first gate insulating layer is disposed between the first semiconductor pattern and the first gate electrode.

5. The semiconductor memory device of claim 4, comprising:
a second semiconductor pattern extending from the first conductive line to the third gate electrode, and
a second information storage element disposed between the second semiconductor pattern and the ground wire,
wherein a second gate insulating layer is disposed between the second semiconductor pattern and the third gate electrode, and
wherein at least a portion of the second semiconductor pattern overlaps with the first semiconductor pattern in the first direction.

6. The semiconductor memory device of claim 4, wherein the first semiconductor pattern comprises a first extrinsic region, a second extrinsic region, and a channel region disposed between the first extrinsic region and the second extrinsic region.

7. The semiconductor memory device of claim 1, wherein the first gate electrode and the second gate electrode are spaced apart from each other in a third direction, the third direction crossing the first direction and the second direction.

8. The semiconductor memory device of claim 7, wherein the first gate electrode and the second gate electrode contact a connection pad that is extending in the third direction.

9. The semiconductor memory device of claim 1, wherein at least a portion of the second gate electrode overlaps with the first gate electrode in the first direction.

10. The semiconductor memory device of claim 9, wherein the contact contacts the first gate electrode and the second gate electrode.

11. A semiconductor memory device, comprising:
a first conductive line extending in a first direction perpendicular to a substrate;
a first gate electrode extending in a second direction on the substrate, the second direction crossing the first direction;
a first semiconductor pattern extending from the first conductive line to the first gate electrode;
a second gate electrode spaced apart from the first gate electrode in a third direction and extending in the second direction on the substrate, the third direction crossing the first direction and the second direction; and
a contact extending in the first direction and electrically connected with the first gate electrode and the second gate electrode.

12. The semiconductor memory device of claim 11, wherein:
the first gate electrode and the second gate electrode contact a connection pad that is extending in the third direction; and
the contact contacts the connection pad.

13. The semiconductor memory device of claim 12, comprising a ground wire disposed between the first gate electrode and the second gate electrode, and spaced apart from the first gate electrode and the second gate electrode in the third direction,
wherein the ground wire is spaced apart from the connection pad in the second direction.

14. The semiconductor memory device of claim 13, comprising:
a second conductive line extending in the first direction and spaced apart from the first conductive line,
a second semiconductor pattern extending from the second conductive line to the second gate electrode,
a first information storage element disposed between the first semiconductor pattern and the ground wire, and
a second information storage element disposed between the second semiconductor pattern and the ground wire,
wherein the first information storage element and the second information storage element are mirror-symmetrically disposed with respect to the ground wire.

15. A semiconductor memory device, comprising:
a first conductive line extending in a first direction perpendicular to a substrate;
a first gate electrode extending in a second direction on the substrate, the second direction crossing the first direction;
a second gate electrode extending in the second direction on the first gate electrode;
a first semiconductor pattern extending from the first conductive line to the first gate electrode; and
a contact extending in the first direction and electrically connected with the first gate electrode and the second gate electrode.

16. The semiconductor memory device of claim 15, wherein the contact contacts the first gate electrode and the second gate electrode.

17. The semiconductor memory device of claim 16, comprising a third gate electrode extending in the second direction on the first gate electrode and the second gate electrode,
wherein each gate electrode of the first gate electrode and the second gate electrode comprises a protrusion region that protrudes in the second direction.

18. The semiconductor memory device of claim 17, wherein the contact contacts the protrusion region of the first gate electrode and the protrusion region of the second gate electrode.

19. The semiconductor memory device of claim 18, wherein the contact extends through the second gate electrode and contacts the first gate electrode.

20. The semiconductor memory device of claim 17, comprising a second semiconductor pattern extending from the first conductive line to the third gate electrode,
wherein the first semiconductor pattern and the second semiconductor pattern are disposed adjacent to each other in the first direction.

21. (canceled)

22. (canceled)

23. (canceled)
